(19) United States
(12) Patent Application Publication
(10) Pub. No.: US 2026/0198042 A1
(43) Pub. Date: Jul. 9, 2026

(54) SEMICONDUCTOR DEVICE DESIGN WITH CAPPING SEMICONDUCTOR LAYER

(71) Applicant: Taiwan Semiconductor Manufacturing Company, Ltd., Hsinchu (TW)

(72) Inventors: Yi-Cheng LI, Yunlin County (TW); Ta-Chun Ma, New Taipei City (TW); Chien-Chia Cheng, Hsinchu County (TW); Ming-Hua Yu, Hsinchu County (TW)

(73) Assignee: Taiwan Semiconductor Manufacturing Company. Ltd, Hsinchu (TW)

(21) Appl. No.: 19/188,517

(22) Filed: Apr. 24, 2025

Related U.S. Application Data
(60) Provisional application No. 63/742,214, filed on Jan. 6, 2025.

(51) Int. Cl. H10D 30/00; H10D 30/01

(52) U.S. Cl. CPC H10D 30/503; H10D 30/0193

(57) ABSTRACT

The present disclosure describes a semiconductor device having a capping semiconductor layer. The semiconductor device includes a channel structure on a substrate, a capping semiconductor layer on a first portion of the channel structure, a gate structure wrapped around the capping semiconductor layer, and a source/drain structure in contact with a second portion of the channel structure. The gate structure includes a gate dielectric layer. The capping semiconductor layer is between the channel structure and gate dielectric layer.

### CROSS-REFERENCE TO RELATED APPLICATION

This application claims the benefit of U.S. Provisional Patent Application No. 63/742,214, titled “Nanosheet MOSFET Design with 2D Material and III-V Semiconductor,” filed January 6, 2025, the disclosure of which is incorporated by reference in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and fin field effect transistors (FinFETs) ), gate-all-around field effect transistors (GAAFETs), complementary field effect transistors (CFETs), nanosheet transistors, nanowire transistors, multi-bridge channel transistors, nano-ribbon transistors, and other similar structured transistors. Such scaling down has increased the complexity of semiconductor manufacturing processes and increased the difficulty of process control in the semiconductor devices.

### BRIEF DESCRIPTION OF THE DRAWINGS

Aspects of the present disclosure are best understood from the following detailed description when read with the accompanying figures.

FIG. 1 illustrates an isometric view of a semiconductor device having a capping semiconductor layer, in accordance with some embodiments.

FIGS. 2-6 illustrate partial cross-sectional views of a semiconductor device having a capping semiconductor layer, in accordance with some embodiments.

FIG. 7 is a flow diagram of a method for fabricating a semiconductor device having a capping semiconductor layer, in accordance with some embodiments.

FIGS. 8-17 illustrate partial cross-sectional views of a semiconductor device having a capping semiconductor layer at various stages of its fabrication, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper,” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 20 % of the value (e.g., ±1 %, ±2 %, ±3 %, ±4 %, ±5 %, ±10 %, ±20 % of the value). These values are merely examples and are not intended to be limiting. The terms “about” and “substantially” can refer to a percentage of the values as interpreted by those skilled in relevant art(s) in light of the teachings herein.

With increasing demand for lower power consumption, higher performance, and smaller semiconductor devices, dimensions of semiconductor devices continue to scale down. The continuous scaling down of device dimensions and the increasing demand for device performance may require various process and material improvements, which can have multiple challenges. For example, a nanostructure transistor on a substrate can have a gate structure wrapped around a channel structure to improve device performance. The nanostructure transistor can have inner spacers to isolate the gate structure from source/drain (S/D) structures around both ends of the channel structure. The channel structure can include silicon or germanium to conduct current between the S/D structures under the control of the gate structure. However, the carrier mobility in silicon and germanium limits the further improvement of device performance and reduction of power consumption.

Various embodiments in the present disclosure provide methods for forming a capping semiconductor layer in a semiconductor device (e.g., a nanostructure transistor) and/or other semiconductor devices in an integrated circuit (IC). In some embodiments, a semiconductor device can include a channel structure on a substrate. A capping semiconductor layer can wrap around a middle portion of the channel structure. A gate structure can wrap around the capping semiconductor layer. A S/D structure can be in contact with an end portion of the channel structure. In some embodiments, the channel structure can have a first length and the capping semiconductor layer can have a second length less than the first length. In some embodiments, the gate structure can include a gate dielectric layer and the capping semiconductor layer can be disposed between the channel structure and the gate dielectric layer. In some embodiments, the capping semiconductor layer can include a two-dimensional (2D) semiconductor material and/or a III-V semiconductor material. In some embodiments, the 2D semiconductor material and III-V semiconductor material can have a higher carrier mobility and a lager bandgap than the semiconductor material in the channel structure. The 2D semiconductor material and III-V semiconductor material can improve device performance and reduce power consumption. In some embodiments, the capping semiconductor layer can be formed after the formation of the channel structure to reduce defects on the capping semiconductor layer and increase carrier mobility of the semiconductor device.

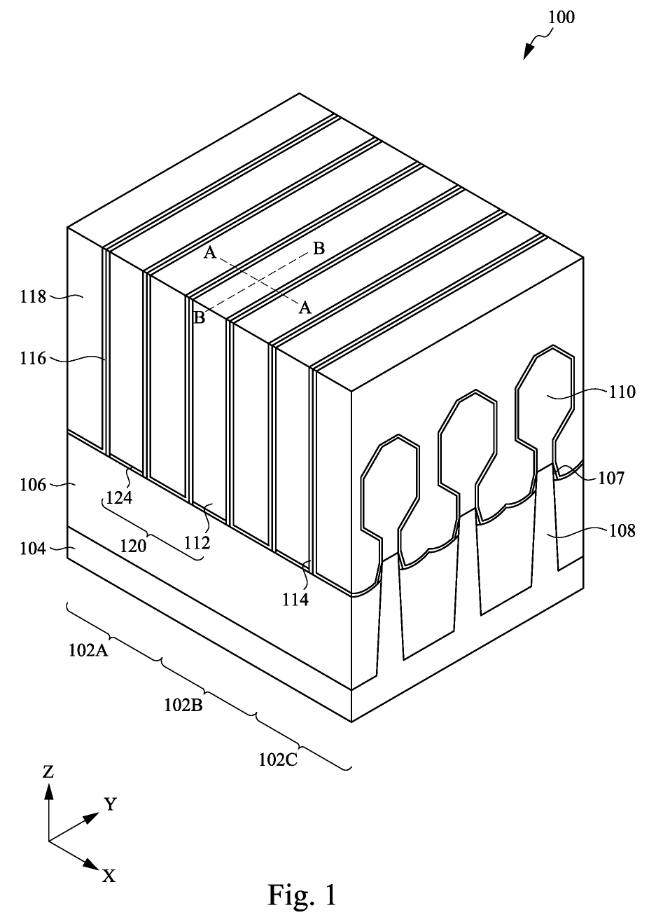

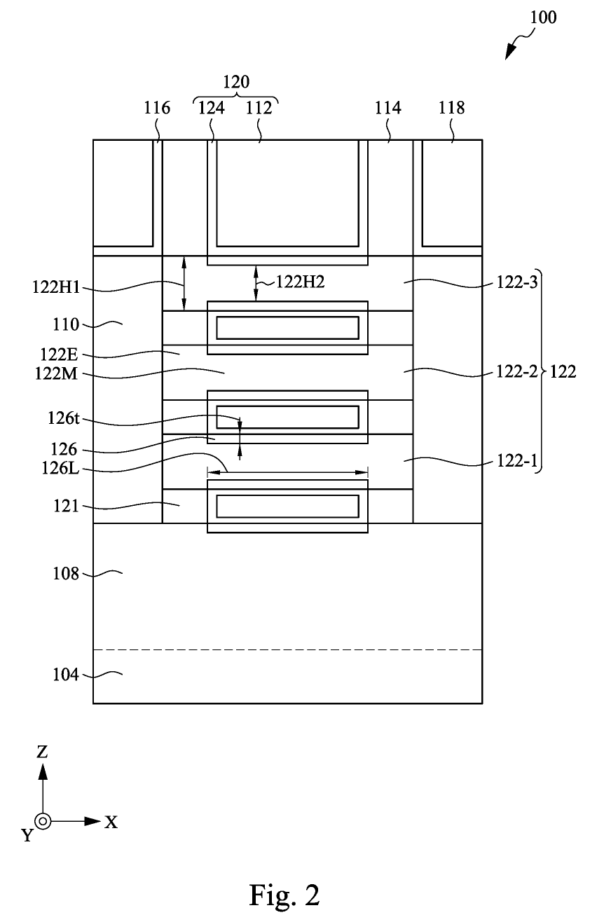

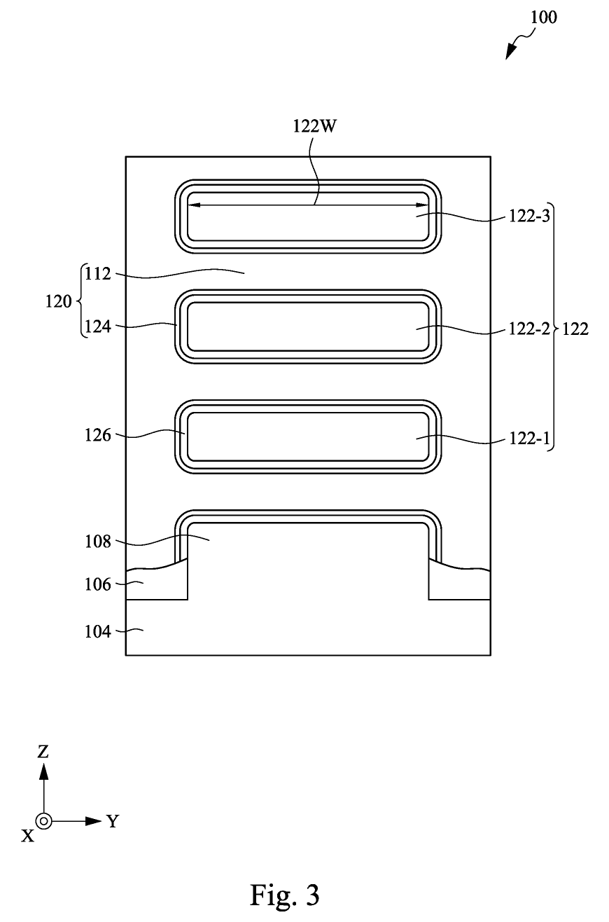

FIG. 1 illustrates an isometric view of a semiconductor device 100 having a capping semiconductor layer, in accordance with some embodiments. FIGS. 2 and 3 illustrate partial cross-sectional views of semiconductor device 100 across lines A-A and B-B shown in FIG. 1, respectively, in accordance with some embodiments. In some embodiments, semiconductor device 100 can include transistors 102A-102C, as shown in FIG. 1. In some embodiments, transistors 102A-102C can include nanostructure transistors. The nanostructure transistors can include FinFETs, gate-all-around field effect transistors (GAA FETs), nanosheet transistors, nanowire transistors, multi-bridge channel transistors, nano-ribbon transistors, and other similar structured transistors. The nanostructure transistors can provide a channel in a stacked nanosheet/nanowire configuration.

In some embodiments, transistors 102A-102C can be n-type field-effect transistors (NFETs). In some embodiments, transistors 102A-102C can be p-type field-effect transistors (PFETs). In some embodiments, any of transistors 102A-102C can be an NFET or a PFET. Though FIG. 1 shows three transistors, semiconductor device 100 can have any number of transistors. In addition, semiconductor device 100 can be incorporated into an IC through the use of other structural components, such as conductive vias, conductive lines, dielectric layers, passivation layers, and interconnects, which are not shown for simplicity. The discussion of elements of transistors 102A-102C with the same annotations applies to each other, unless mentioned otherwise. And like reference numerals generally indicate identical, functionally similar, and/or structurally similar elements.

Referring to FIGS. 1-6, semiconductor device 100 having transistors 102A-102C can be formed on a substrate 104 and can be isolated by shallow trench isolation (STI) regions 106. Each of transistors 102A-102C can include fin base structures 108, nanostructures 122-1, 122-2, and 122-3 (collectively referred to as “nanostructures 122”), a capping layer 126, sidewall spacers 107, gate structures 120, gate spacers 114, inner spacers 121, S/D structures 110, an etch stop layer (ESL) 116, and an interlayer dielectric (ILD) layer 118.

Referring to FIGS. 1-6, substrate 104 can include a semiconductor material, such as silicon. In some embodiments, substrate 104 includes a crystalline silicon substrate (e.g., wafer). In some embodiments, substrate 104 includes (i) an elementary semiconductor, such as germanium; (ii) a compound semiconductor including silicon carbide, gallium arsenide, gallium phosphide, indium phosphide, indium arsenide, and/or indium antimonide; (iii) an alloy semiconductor including silicon germanium carbide, silicon germanium, gallium arsenic phosphide, and/or aluminum gallium arsenide; or (iv) a combination thereof. Further, substrate 104 can be doped depending on design requirements (e.g., p-type substrate or n-type substrate). In some embodiments, substrate 104 can be doped with p-type dopants (e.g., boron, indium, aluminum, or gallium) or n-type dopants (e.g., phosphorus or arsenic).

STI regions 106 can provide electrical isolation between transistors 102A-102C and from neighboring transistors (not shown) on substrate 104 and/or neighboring active and passive elements (not shown) integrated with or deposited on substrate 104. STI regions 106 can be made of a dielectric material. In some embodiments, STI regions 106 can include silicon oxide, silicon nitride, silicon oxynitride, fluorine-doped silicate glass (FSG), a low-k dielectric material, and/or other suitable insulating materials. In some embodiments, STI regions 106 can include a multi-layered structure.

Referring to FIGS. 1-6, nanostructures 122 and fin base structures 108 can be formed on patterned portions of substrate 104. Embodiments of the nanostructures and fin base structures disclosed herein may be patterned by any suitable method. For example, the nanostructures and fin base structures may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process. For example, a sacrificial layer is formed over a substrate and patterned using a photolithography process. Spacers can be formed alongside the patterned sacrificial layer using a self-aligned process. The sacrificial layer is then removed, and the remaining spacers can then be used to pattern the nanostructures and fin base structures.

As shown in FIGS. 1-6, nanostructures 122 and fin base structures 108 can extend along an X-axis for transistors 102A-102C. In some embodiments, nanostructures 122 and fin base structures 108 can be disposed on substrate 104. Nanostructures 122 can include a set of nanostructures 122-1, 122-2, and 122-3, which can be in the form of semiconductor layers, nanosheets, nanowires, or nano-ribbons. Each of nanostructures 122 can act as a channel structure underlying gate structures 120 of transistors 102A-102C. In some embodiments, nanostructures 122 and fin base structures 108 can include semiconductor materials similar to or different from substrate 104. In some embodiments, nanostructures 122 and fin base structures 108 can include silicon. The semiconductor materials of nanostructures 122 and fin base structures 108 can be undoped or can be in-situ doped during their formation process. In some embodiments, as shown in FIGS. 2 and 3, nanostructures 122 under gate structures 120 can form channel regions of semiconductor device 100 and represent current carrying channel structures of semiconductor device 100. Though three layers of nanostructures 122 are shown in FIGS. 2 and 3, transistors 102A-102C can have any number of nanostructures 122. In some embodiments, the number of nanostructures 122 can range from about 1 to about 5.

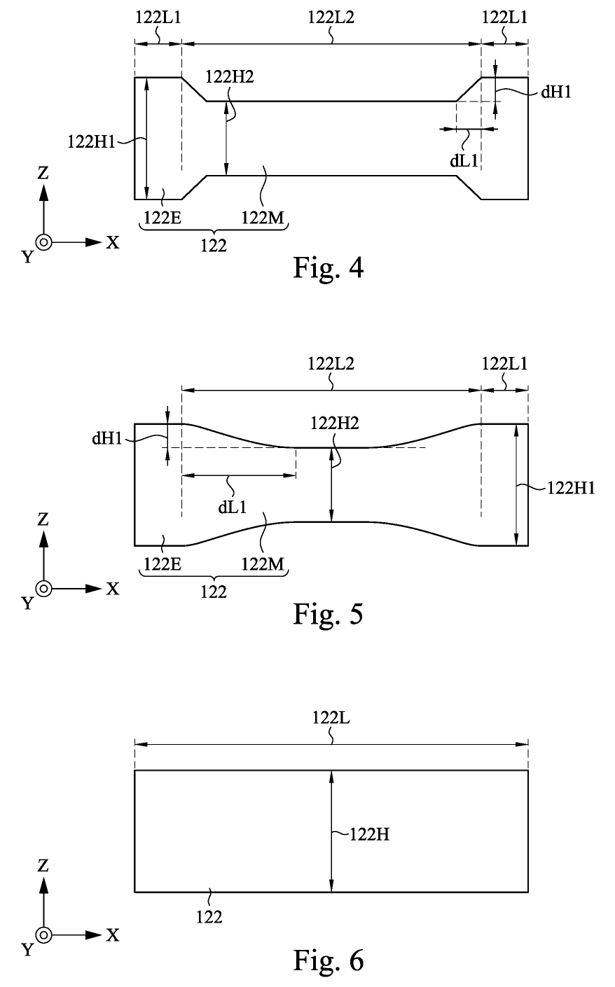

In some embodiments, as shown in FIGS. 2, 4, and 5, each of nanostructures 122 can have a “dog-bone” profile and can include an edge portion 122E and a middle portion 122M narrower than edge portion 122E. Edge portion 122E can be wrapped around by inner spacers 121. Middle portion 122M can be wrapped around by capping layer 126 and gate structures 120. In some embodiments, for nanostructures 122 having a dog-bone profile as shown in FIG. 2, capping layer 126 can be in contact with gate structures 120, middle portion 122M, and end portion 122E of nanostructures 122. In some embodiments, as shown in FIG. 3, nanostructures 122 can have a width 122W along a Y-axis ranging from about 10 nm to about 80 nm. In some embodiments, as shown in FIGS. 4 and 5, edge portion 122E can have a height 122H1 along a Z-axis ranging from about 3 nm to about 10 nm. Middle portion 122M can have a height 122H2 along a Z-axis ranging from about 2 nm to about 8 nm. In some embodiments, height 122H2 can be referred to as the “thickness of the channel structure” of semiconductor device 100. In some embodiments, edge portion 122E can have a length 122L1 along an X-axis ranging from about 2 nm to about 8 nm. Middle portion 122M can have a length 122L2 ranging from about 5 nm to about 30 nm. In some embodiments, a space between edge portions 122E of adjacent nanostructures 122 can range from about 2 nm to about 13 nm. In some embodiments, a space between middle portions 122M of adjacent nanostructures 122 can range from about 3 nm to about 15 nm. In some embodiments, a height dH1 between edge portion 122E and middle portion 122M on a top surface of nanostructure 122 can range from about 0 nm to about 6 nm. In some embodiments, a length dL1 of a transition portion in middle portion 122M of nanostructure 122 can range from about 0 nm to about 6 nm. In some embodiments, one of n-type nanostructures 122 and one or p-type nanostructures 122 can have a substantially same height 122H2. In some embodiments, a difference of height 122H2 between n-type nanostructures 122 and p-type nanostructures 122 can range from about 0 nm to about 3 nm. In some embodiments, n-type and p-type nanostructures 122 can have a substantially same length 122L2. In some embodiments, a difference of length 122L2 between n-type and p-type nanostructures 122 can range from about 0 nm to about 3 nm. In some embodiments, a difference of height dH1 between n-type and p-type nanostructures 122 can range from about 0 nm to about 3 nm. In some embodiments, a difference of length dL1 between n-type and p-type nanostructures 122 can range from about 0 nm to about 3 nm. In some embodiments, heights 122H1 and 122H2, lengths 122L1 and 122L2, height dH1, length dL1, the spaces, the height differences, and the length differences can be within these ranges to improve the device performance of semiconductor device 100.

In some embodiments, as shown in FIG. 6, one of nanostructures 122 can have a square profile with the end portion and the middle portion having a substantially same height. In some embodiments, for nanostructures 122 having a square profile, capping layer 126 can be in contact with gate structures 120, inner spacers 121, and middle portion 122M of nanostructures 122. In some embodiments, as shown in FIG. 6, nanostructures 122 can have a height 122H ranging from about 3 nm to about 10 nm. Nanostructures 122 can have a length 122L ranging from about 20 nm to about 40 nm. In some embodiments, length 122L of nanostructures 122 can be substantially equal to a sum of length 122L2 of middle portion 122M and two times length 122L1 of end portion 122E. In some embodiments, n-type and p-type nanostructures 122 can have a substantially same height 122H. In some embodiments, a height difference between n-type and p-type nanostructures 122 can range from about 0 nm to about 3 nm. In some embodiments, n-type and p-type nanostructures 122 can have a substantially same length 122L. In some embodiments, a length difference between n-type and p-type nanostructures 122 can range from about 0 nm to about 3 nm. In some embodiments, heights 122H, lengths 122L, the height difference, and the length difference can be within these ranges to improve the device performance of semiconductor device 100.

In some embodiments, as shown in FIGS. 2 and 3, capping layer 126 can wrap around middle portion 122M of nanostructures 122. In some embodiments, capping layer 126 can include a 2D semiconductor material, such as molybdenum disulfide, molybdenum diselenide, molybdenum ditelluride, tungsten disulfide, and tungsten diselenide. In some embodiments, capping layer 126 can include a III-V semiconductor material, such as gallium nitride, gallium arsenide, gallium antimonide, indium phosphide, indium antimonide, indium gallium phosphide, and indium gallium arsenide. Accordingly, in some embodiments, capping layer 126 can be referred to as “capping semiconductor layer 126.” In some embodiments, capping semiconductor layer 126 can include a multi-layered structure. In some embodiments, capping semiconductor layer 126 can include a layer of 2D semiconductor material and a layer of III-V semiconductor material. In some embodiments, the layer of 2D semiconductor material can be in contact with nanostructures 122 and the layer of III-V semiconductor material can be in contact with gate structures 120. In some embodiments, the layer of III-V semiconductor material can be in contact with nanostructures 122 and the layer of 2D semiconductor material can be in contact with gate structures 120. In some embodiments, capping semiconductor layer 126 can conduct current between S/D regions of semiconductor device 100 and act as “channel regions” of semiconductor device 100. In some embodiments, capping semiconductor layer 126 can have a higher carrier mobility and a larger bandgap than nanostructures 122. As a result, capping semiconductor layer 126 can increase the device on-current, reduce leakage current, improve device performance, and reduce power consumption.

In some embodiments, capping semiconductor layer 126 can wrap around middle portion 122M of nanostructures 122 and can have a length 126L ranging from about 5 nm to about 30 nm. In some embodiments, length 126L can be less than length 122L of nanostructures 122. In some embodiments, a ratio of length 126L to length 122L can range from about 0.2 to about 0.8. If length 126L is less than about 5nm, or the ratio is less than about 0.2, short channel effect may increase and device performance may decrease. If length 126L is greater than about 30 nm, or the ratio is greater than about 0.8, inner spacers 121 may not fully isolate gate structures 120 from S/D structures 110.

In some embodiments, capping semiconductor layer 126 can have a thickness 126t along a Z-axis ranging from about 0.3 nm to about 6 nm. In some embodiments, a ratio of thickness 126t to height 122H2 of middle portion 122M can range from about 0.1 to about 0.4. If thickness 126t is less than about 0.3 nm or the ratio is less than about 0.1, capping semiconductor layer 126 may not improve device performance or reduce power consumption. If thickness 126t is greater than about 6 nm or the ratio is greater than about 0.4, spaces between adjacent nanostructures 122 can be reduced and gate structures 120 may not fill in the spaces and may not wrap around nanostructures 122.

In some embodiments, capping semiconductor layer 126 can include a 2D semiconductor material and thickness 126t can range from about 0.3 nm to about 3 nm. If thickness 126t is less than about 0.3 nm, the 2D semiconductor material may not be deposited on nanostructures 122 and capping semiconductor layer 126 may not conduct current. If thickness 126t is greater than about 3 nm, spaces between adjacent nanostructures 122 can be reduced and gate structures 120 may not wrap around nanostructures 122. In some embodiments, capping semiconductor layer 126 can include a III-V semiconductor material and thickness 126t can range from about 1 nm to about 6 nm. If thickness 126t is less than about 1 nm, the carrier mobility of the III-V semiconductor material may be reduced and device performance may not be improved. If thickness 126t is greater than about 6 nm, spaces between adjacent nanostructures 122 can be reduced and gate structures 120 may not wrap around nanostructures 122.

In some embodiments, capping semiconductor layer 126 of n-type and p-type transistors can include the same 2D semiconductor material. In some embodiments, capping semiconductor layer 126 of n-type and p-type transistors can include different III-V semiconductor materials to increase both n-type and p-type carrier mobilities. For example, capping semiconductor layer 126 of n-type transistors 102A-102C can include 2D semiconductor materials such as transition metal dichalcogenide or III-V semiconductor materials such as gallium arsenide, gallium antimonide, and indium phosphide. Capping semiconductor layer 126 of p-type transistors 102A-102C can include 2D semiconductor materials such as transition metal dichalcogenide or III-V semiconductor materials such as gallium nitride and indium gallium arsenide.

Referring to FIGS. 1-6, gate structures 120 can include gate dielectric layer 124 and gate electrode 112. In some embodiments, gate dielectric layer 124 can be formed on capping semiconductor layer 126 and STI regions 106. In some embodiments, gate dielectric layer 124 can be multi-layered structures and can include an interfacial layer and a high-k dielectric layer. In some embodiments, gate dielectric layer 124 can include no interfacial layer and a high-k dielectric layer in direct contact with capping semiconductor layer 126. In some embodiments, the interfacial layer can include silicon oxide formed by a deposition process. In some embodiments, the interfacial layer can have a thickness ranging from about 0.1 nm to about 1.5 nm. In some embodiments, the high-k dielectric layer can include hafnium oxide, zirconium oxide, or other suitable high-k dielectric materials. In some embodiments, capping semiconductor layer 126 can be disposed between gate dielectric layer 124 and nanostructures 122.

In some embodiments, as shown in FIGS. 1-6, gate electrode 112 can be disposed on gate dielectric layer 124. In some embodiments, gate electrode 112 can be referred to as the “metal gate” of transistors 102A-102C. In some embodiments, gate electrode 112 can include one or more work function metal layers and a metal fill. The one or more work function metal layers can include work function metals to tune the threshold voltage (Vₜ) of transistors 102A-102C. In some embodiments, gate electrode 112 for NFET and PFET devices can have the same work-function metal. In some embodiments, gate electrode 112 for NFET and PFET devices can have different work-function metals. In some embodiments, as shown in FIG. 2 and 3, each of nanostructures 122 can be wrapped around by gate structures 120, for which gate structures 120 can be referred to as “gate-all-around (GAA) structures” and transistors 102A-102C can also be referred to as “GAA FETs 102A-102C.” The one or more work function metal layers can wrap around nanostructures 122 and can include work function metals to tune the Vₜ of transistors 102A-102C. In some embodiments, transistors 102A-102C can include any number of work function metal layers for Vₜ tuning (e.g., ultra-low Vₜ, low Vₜ, and standard Vₜ).

In some embodiments, NFETs 102A-102C can include n-type work function metal layers. The n-type work function metal layers can include aluminum, titanium aluminum, titanium aluminum carbon, tantalum aluminum, tantalum aluminum carbon, tantalum silicon carbide, hafnium carbide, silicon, titanium nitride, titanium silicon nitride, or other suitable work function metals. In some embodiments, PFETs 102A-102C can include p-type work function metal layers. The p-type work function metal layers can include titanium nitride, titanium silicon nitride, tantalum nitride, tungsten carbon nitride, tungsten, molybdenum, or other suitable work function metals. In some embodiments, the work function metal layers can include a single metal layer or a stack of metal layers. The stack of metal layers can include work function metals having work-function values equal to or different from each other. In some embodiments, the metal fill can include titanium, tantalum, aluminum, cobalt, tungsten, nickel, ruthenium, or other suitable conductive materials.

Referring to FIGS. 1-6, gate spacers 114 can be disposed on sidewalls of gate structures 120, sidewall spacers 107 can be disposed on sidewalls of fin base structures 108, and inner spacers 121 can be disposed between gate structures 120 and S/D structures 110. Gate spacers 114, sidewall spacers 107, and inner spacers 121 can include insulating materials, such as silicon oxide, silicon nitride, silicon oxynitride, silicon carbonitride, silicon oxycarbide, silicon oxycarbonitride, a low-k material, and a combination thereof. In some embodiments, gate spacers 114, sidewall spacers 107, and inner spacers 121 can include a same insulating material. In some embodiments, gate spacers 114, sidewall spacers 107, and inner spacers 121 can include different insulating materials. Gate spacers 114, sidewall spacers 107, and inner spacers 121 can include a single layer or a stack of insulating layers. Gate spacers 114, sidewall spacers 107, and inner spacers 121 can have a low-k material with a dielectric constant less than about 3.9 (e.g., about 3.5, about 3.0, or about 2.8). In some embodiments, as shown in FIG. 2, inner spacers 121 can be in contact with gate structures 120, end portion 122E of nanostructures 122, and S/D structures 110.

S/D structures 110 can be disposed on fin base structures 108 and in contact with nanostructures 122. In some embodiments, S/D structures 110 can be disposed between adjacent stacks of nanostructures 122 and on opposing sides of gate structures 120. S/D structures 110 can function as S/D regions of transistors 102A-102C. In some embodiments, S/D structures 110 can have any geometric shape, such as a polygon, an ellipse, and a circle. In some embodiments, S/D structures 110 can include an epitaxially-grown semiconductor material, such as silicon (e.g., the same material as substrate 104). In some embodiments, the epitaxially-grown semiconductor material can include an epitaxially-grown semiconductor material different from the material of substrate 104, such as silicon germanium, and imparts a strain on the channel regions under gate structures 120. Since the lattice constant of such epitaxially-grown semiconductor material is different from the material of substrate 104, nanostructures 122 are strained to increase carrier mobility in the channel regions of semiconductor device 100. The epitaxially-grown semiconductor material can include: (i) a semiconductor material, such as germanium and silicon; (ii) a compound semiconductor material, such as gallium arsenide and aluminum gallium arsenide; or (iii) a semiconductor alloy, such as silicon germanium and gallium arsenide phosphide.

In some embodiments, S/D structures 110 can include silicon and can be in-situ doped during an epitaxial growth process using n-type dopants, such as phosphorus and arsenic. In some embodiments, S/D structures 110 can include silicon, silicon germanium, germanium, or III-V materials (e.g., indium antimonide, gallium antimonide, or indium gallium antimonide) and can be in-situ doped during an epitaxial growth process using p-type dopants, such as boron, indium, and gallium. In some embodiments, S/D structures 110 can include one or more epitaxial layers, where each epitaxial layer can have different compositions. In some embodiments, S/D structures 110 can have a width along an X-axis ranging from about 20 nm to about 40 nm. In some embodiments, S/D structures 110 can have a height along a Z-axis ranging from about 50 nm to about 100 nm. In some embodiments, as shown in FIG. 2, S/D structures 110 can be in contact with end portion 122E of nanostructures 122.

Referring to FIGS. 1-6, ESL 116 can be disposed on STI regions 106, S/D structures 110, and sidewalls of gate spacers 114 and sidewall spacers 107. ESL 116 can be configured to protect STI regions 106, S/D structures 110, and gate structures 120 during the formation of S/D contact structures on S/D structures 110. In some embodiments, ESL 116 can include, for example, silicon oxide, silicon nitride, silicon oxynitride, silicon carbide, silicon carbonitride, boron nitride, silicon boron nitride, silicon carbon boron nitride, or a combination thereof.

ILD layer 118 can be disposed on ESL 116 over S/D structures 110 and STI regions 106. ILD layer 118 can include a dielectric material deposited using a deposition method suitable for flowable dielectric materials. For example, flowable silicon oxide can be deposited using flowable chemical vapor deposition (FCVD). In some embodiments, the dielectric material can include silicon oxide.

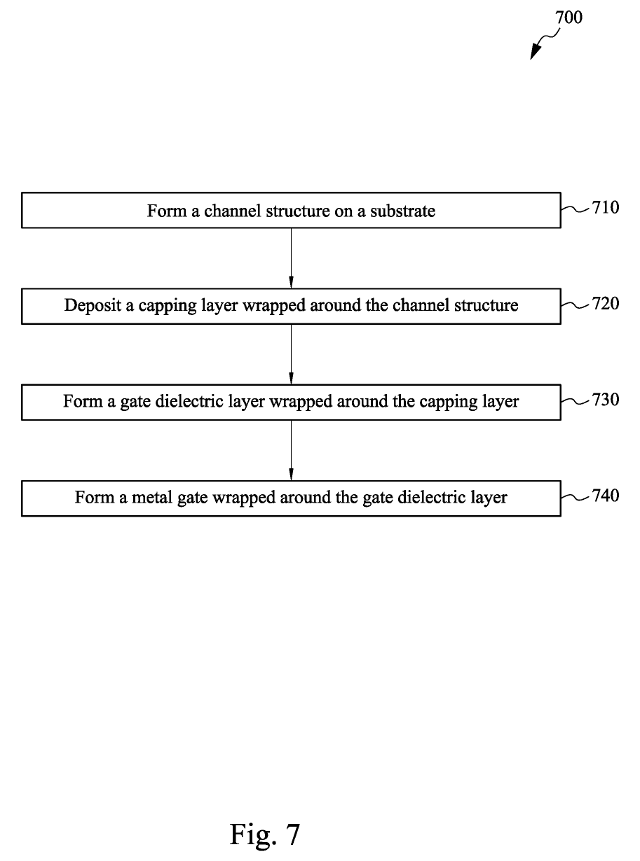

FIG. 7 is a flow diagram of a method 700 for fabricating semiconductor device 100 having a capping semiconductor layer, in accordance with some embodiments. Method 700 may not be limited to nanostructure transistor devices and can be applicable to other devices that would benefit from the capping semiconductor layer. Additional fabrication operations may be performed between various operations of method 700 and may be omitted merely for clarity and ease of description. Additional processes can be provided before, during, and/or after method 700; one or more of these additional processes are briefly described herein. Moreover, not all operations may be needed to perform the disclosure provided herein. Additionally, some of the operations may be performed simultaneously or in a different order than shown in FIG. 7. In some embodiments, one or more other operations may be performed in addition to or in place of the presently-described operations.

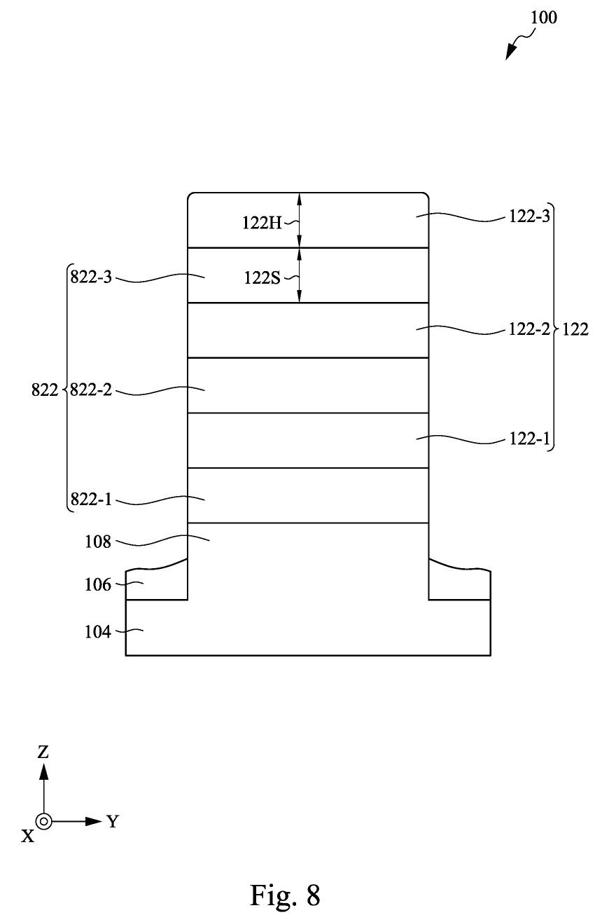

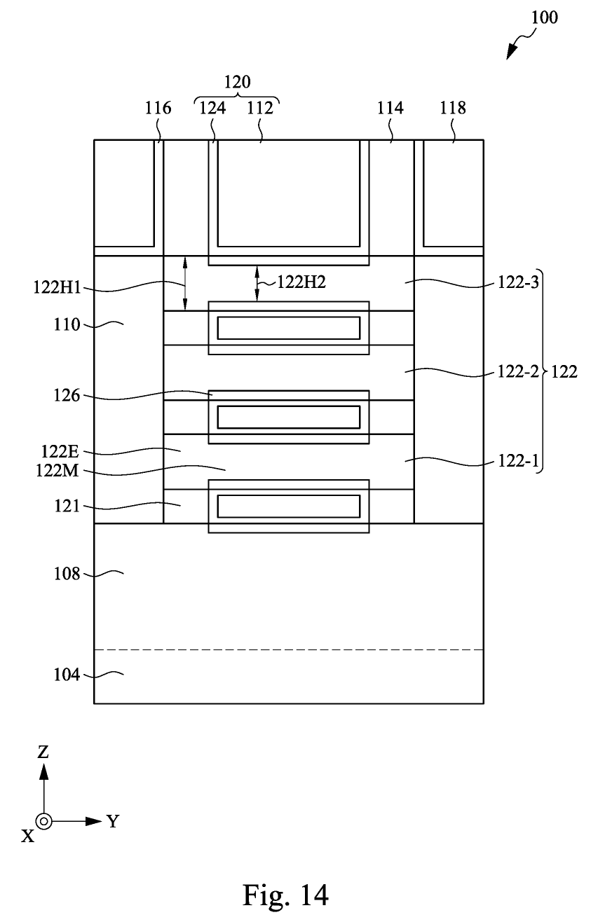

For illustrative purposes, the operations illustrated in FIG. 7 will be described with reference to the example fabrication process for fabricating semiconductor device 100 as illustrated in FIGS. 8-17. FIGS. 8-17 illustrate partial cross-sectional views of semiconductor device 100 having a capping semiconductor layer at various stages of its fabrication, in accordance with some embodiments. In some embodiments, FIGS. 8-13 illustrate partial cross-sectional views of semiconductor device 100 across line B-B shown in FIG. 1. In some embodiments, FIGS. 14-17 illustrate partial cross-sectional views of semiconductor device 100 across line A-A shown in FIG. 1. In some embodiments, elements in FIGS. 8-17 with the same annotations as elements in FIGS. 1-6 are described above.

In referring to FIG. 7, method 700 begins with operation 710 and the process of forming a channel structure on a substrate. For example, as shown in FIGS. 7-10, nanostructures 122 and fin base structures 108 can be formed on substrate 104. In some embodiments, nanostructures 122 can act as the channel structure of semiconductor device 100. In some embodiments, the formation of the channel structure can include the deposition of a stack of semiconductor layers on substrate 104, a patterning process to form nanostructures 122 and nanostructures 822-1, 822-2, and 822-3 (collectively referred to as “nanostructures 822”), removal of nanostructures 822, and optional trimming of nanostructures 122. In some embodiments, the stack of semiconductor layers can include different semiconductor materials stacked in an alternate configuration. In some embodiments, the stack of semiconductor layers can be epitaxially grown on substrate 104.

In some embodiments, the formation of the stack of semiconductor layers can be followed by a patterning process to form nanostructures 122 and 822. For example, as shown in FIG. 8, the stack of semiconductor layers can be patterned to form nanostructures 122 and 822 and fin base structures 108 on substrate 104. In some embodiments, nanostructures 122 and 822 can be in the form of semiconductor layers, nanosheets, nanowires, or nano-ribbons. In some embodiments, fin base structures 108 can include the same semiconductor material as substrate 104. In some embodiments, nanostructures 122 and 822 can include semiconductor materials similar to or different from substrate 104. In some embodiments, nanostructures 122 and 822 can include different semiconductor materials. In some embodiments, nanostructures 822 can include silicon germanium with a germanium concentration ranging from about 20 % to about 60 %. In some embodiments, nanostructures 122 can include silicon. In some embodiments, each of nanostructures 122 can have a height 122H along a Z-axis ranging from about 3 nm to about 10 nm. In some embodiments, a space 122S along a Z-axis between adjacent nanostructures 122 can range from about 3 nm to about 15 nm. In some embodiments, space 122S can be equal to a height of nanostructures 822 along a Z-axis.

Embodiments of fin base structures 108 and nanostructures 122 and 822 disclosed herein may be patterned by any suitable method. For example, the fin base structures and the nanostructures may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process. For example, a sacrificial layer is formed over a substrate and patterned using a photolithography process. Spacers can be formed alongside the patterned sacrificial layer using a self-aligned process. The sacrificial layer is then removed, and the remaining spacers can then be used to pattern the fin base structures and the nanostructures.

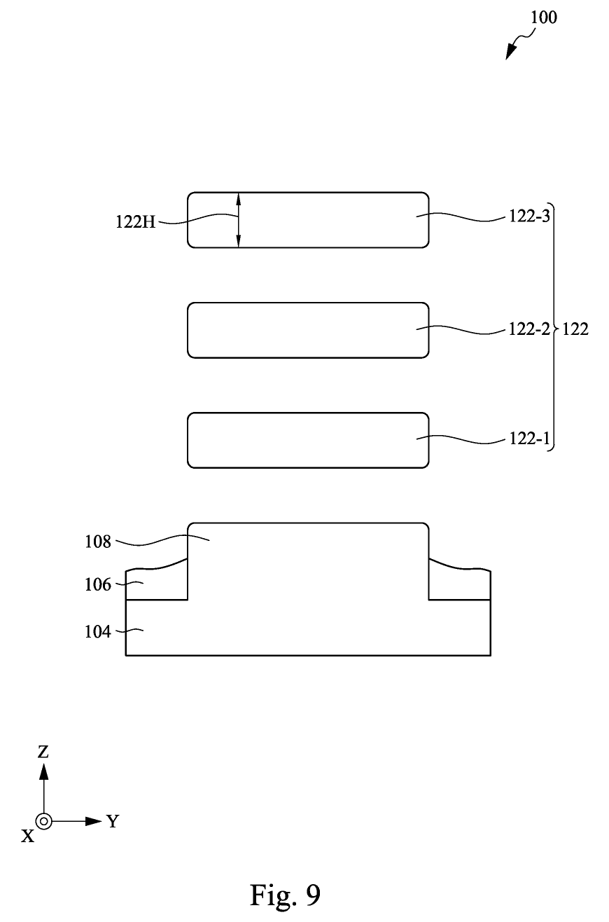

In some embodiments, the formation of nanostructures 122 and 822 can include the formation of STI regions 106, the formation of inner spacers 121, and the formation of S/D structures 110, which are not described in detail for clarity. In some embodiments, the formation of S/D structures 110 can be followed by removal of nanostructures 822 and release of nanostructures 122. For example, as shown in FIG. 9, nanostructures 822 can be removed by an etching process and nanostructures 122 can form the channel structure of semiconductor device 100. In some embodiments, the etching process can be a selective etching process to remove nanostructures 822.

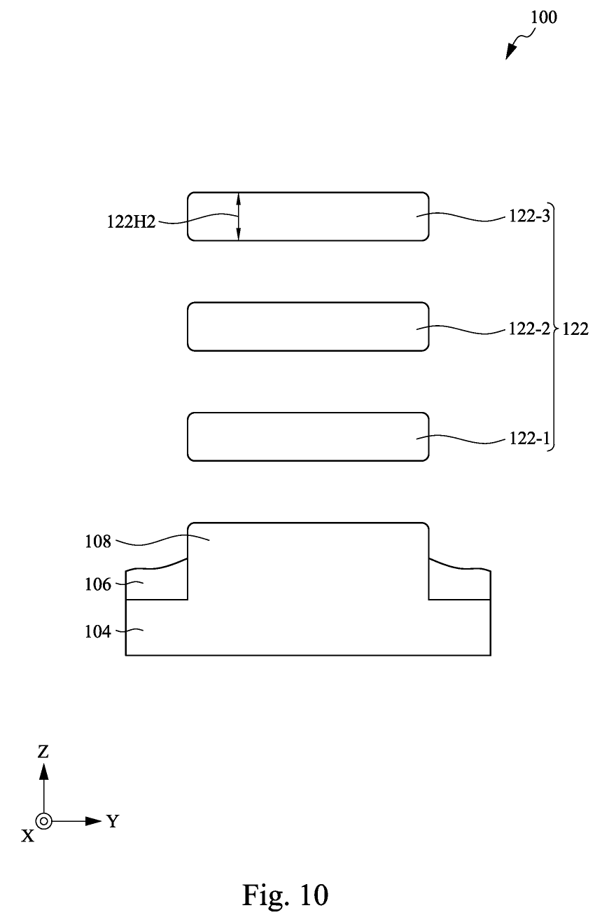

In some embodiments, the removal of nanostructures 822 can be followed by an optional trimming process of nanostructures 122. For example, as shown in FIG. 10, middle portions of nanostructures 122 can be optionally trimmed. In some embodiments, After the optional trimming process, height 122H2 of nanostructures 122 can range from about 2 nm to about 8 nm. In some embodiments, the trimming process can reduce the thickness of nanostructures 122 and increase the space between adjacent nanostructures 122, which can improve the process window of subsequent formation of gate structures 120.

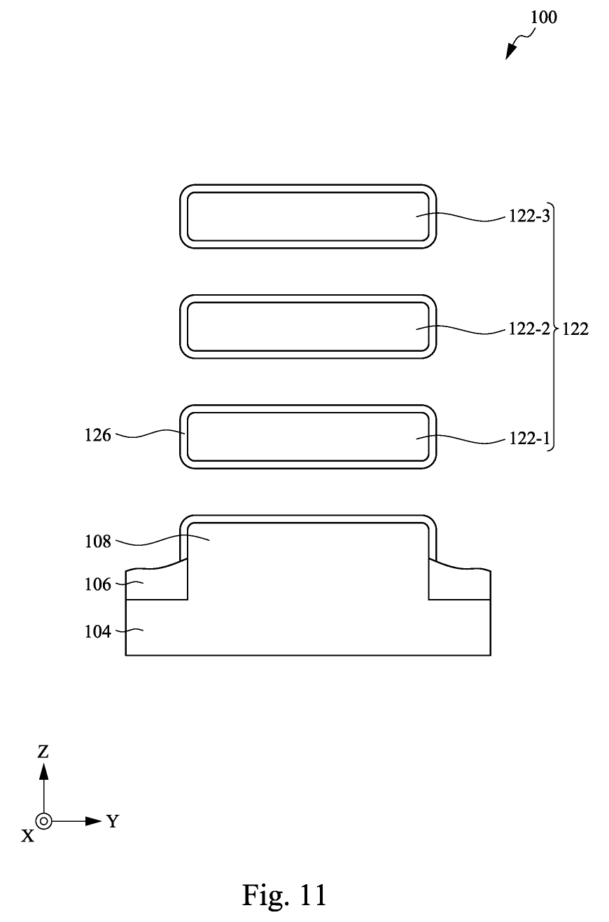

Referring to FIG. 7, in operation 720, a capping layer is deposited to wrap around the channel structure. For example, as shown in FIG. 11, capping semiconductor layer 126 can be conformally deposited on nanostructures 122 and fin base structures 108. Capping semiconductor layer 126 can wrap around nanostructures 122. In some embodiments, capping semiconductor layer 126 can be formed after the release of nanostructures 122 to reduce defects on capping semiconductor layer 126 and increase the carrier mobility of semiconductor device 100. In some embodiments, capping semiconductor layer 126 can be conformally deposited by atomic layer deposition (ALD), chemical vapor deposition (CVD), or other suitable deposition methods. In some embodiments, capping semiconductor layer 126 can include a 2D semiconductor material or a III-V semiconductor material.

In some embodiments, the 2D semiconductor material can be deposited by CVD at a temperature from about 600 ℃ to about 900 ℃ under a pressure from about 1 torr to about 200 torr. In some embodiments, the 2D semiconductor material can be deposited by salt-assisted CVD at a temperature from about 200 ℃ to about 500 ℃ under a pressure from about 1 torr to about 200 torr. In some embodiments, the III-V semiconductor material can be deposited by ALD at a temperature from about 400 ℃ to about 1100 ℃ under a pressure from about 0.1 torr to about 760 torr. In some embodiments, the III-V semiconductor material can be deposited by CVD at a temperature from about 400 ℃ to about 1100 ℃ under a pressure from about 1 torr to about 760 torr. In some embodiments, capping semiconductor layer 126 can include molybdenum disulfide and can be deposited with precursors include molybdenum hexacarbonyl (Mo(CO)₆), molybdenum chloride (MoCl₅), and hydrogen sulfide (H₂S). In some embodiments, capping semiconductor layer 126 can include tungsten disulfide and can be deposited with precursors include tungsten hexacarbonyl (W(CO)₆), tungsten chloride (WCl₆), and hydrogen sulfide (H₂S).

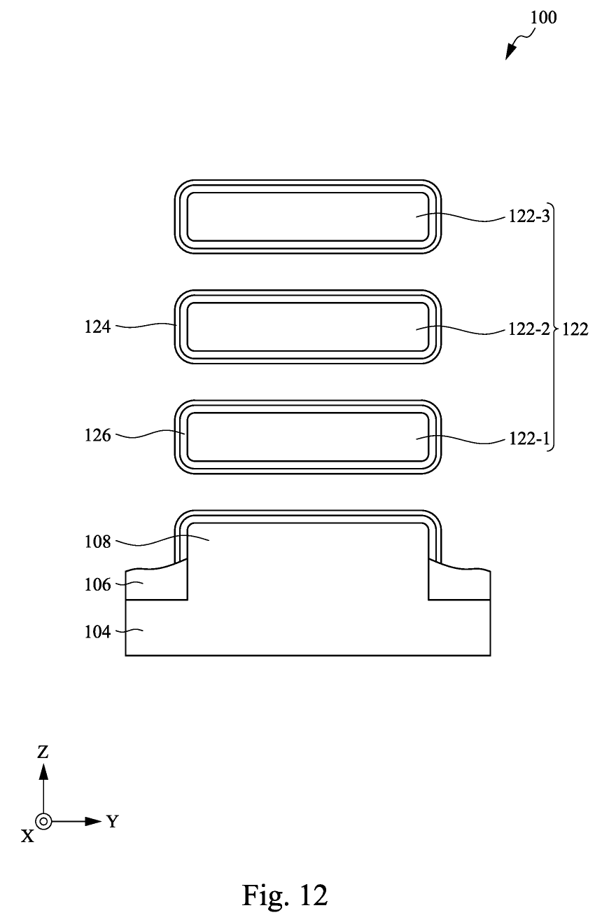

Referring to FIG. 7, in operation 730, a gate dielectric layer is formed to wrap around the capping layer. For example, as shown in FIG. 12, gate dielectric layer 124 can be formed on capping semiconductor layer 126 and can wrap around capping semiconductor layer 126 and nanostructures 122. In some embodiments, gate dielectric layer 124 can be multi-layered structures and can include an interfacial layer and a high-k dielectric layer. In some embodiments, gate dielectric layer 124 can include no interfacial layer and a high-k dielectric layer in direct contact with capping semiconductor layer 126. In some embodiments, the interfacial layer can include silicon oxide formed by a deposition process. In some embodiments, the interfacial layer can have a thickness ranging from about 0.1 nm to about 1.5 nm. In some embodiments, the high-k dielectric layer can include hafnium oxide, zirconium oxide, or other suitable high-k dielectric materials. In some embodiments, capping semiconductor layer 126 can be disposed between gate dielectric layer 124 and nanostructures 122.

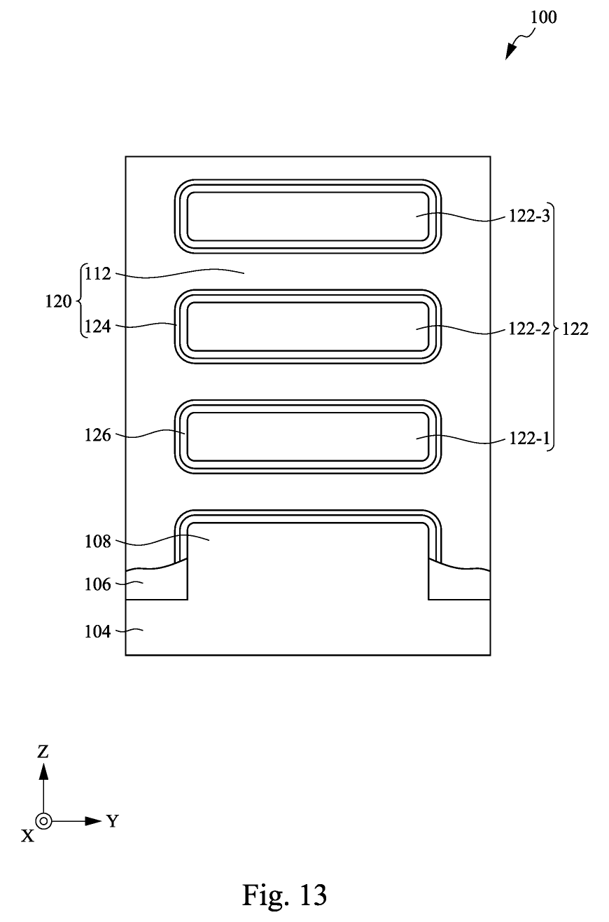

Referring to FIG. 7, in operation 740, a metal gate is formed to wrap around the gate dielectric layer. For example, as shown in FIGS. 13 and 14, gate electrode 112 can be formed on gate dielectric layer 124 and can wrap around gate dielectric layer 124, capping semiconductor layer 126, and nanostructures 122. In some embodiments, as shown in FIG. 14, middle portion 122M is trimmed and capping semiconductor layer 126 can be in contact with end portion 122E, middle portion 122M, and gate dielectric layer 124. In some embodiments, gate electrode 112 can include one or more work function metal layers and a metal fill. The one or more work function metal layers can include work function metals to tune the Vₜ of transistors 102A-102C. The one or more work function metal layers can wrap around nanostructures 122 and can include work function metals to tune the Vₜ of transistors 102A-102C.

In some embodiments, NFETs 102A-102C can include n-type work function metal layers. In some embodiments, PFETs 102A-102C can include p-type work function metal layers. In some embodiments, the work function metal layers can include a single metal layer or a stack of metal layers. The stack of metal layers can include work function metals having work-function values equal to or different from each other. In some embodiments, the metal fill can include titanium, tantalum, aluminum, cobalt, tungsten, nickel, ruthenium, or other suitable conductive materials.

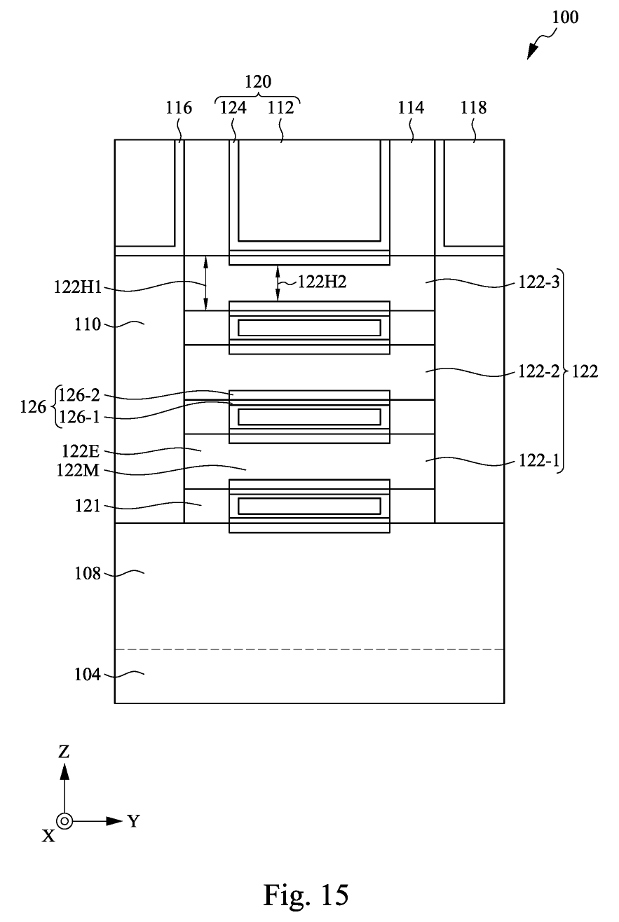

In some embodiments, the 2D and III-V semiconductor material in capping semiconductor layer 126 can have a higher carrier mobility and a lager bandgap. Accordingly, capping semiconductor layer 126 can increase the device on-current, reduce leakage current, improve device performance, and reduce power consumption of semiconductor device 100. In some embodiments, as shown in FIG. 15, capping semiconductor layer 126 can be a multi-layered structure and can include first capping semiconductor layer 126-1 and second capping semiconductor layer 126-2. In some embodiments, first capping semiconductor layer 126-1 can include a 2D semiconductor material or a III-V semiconductor material. In some embodiments, second capping semiconductor layer 126-2 can include a 2D semiconductor material or a III-V semiconductor material. In some embodiments, capping semiconductor layer 126 can include any number of layers of 2D semiconductor material and III-V semiconductor material. In some embodiments, a layer of 2D semiconductor material can have a thickness along a Z-axis from about 0.3 nm to about 3 nm. In some embodiments, a layer of III-V semiconductor material can have a thickness along a Z-axis from about 1 nm to about 6 nm.

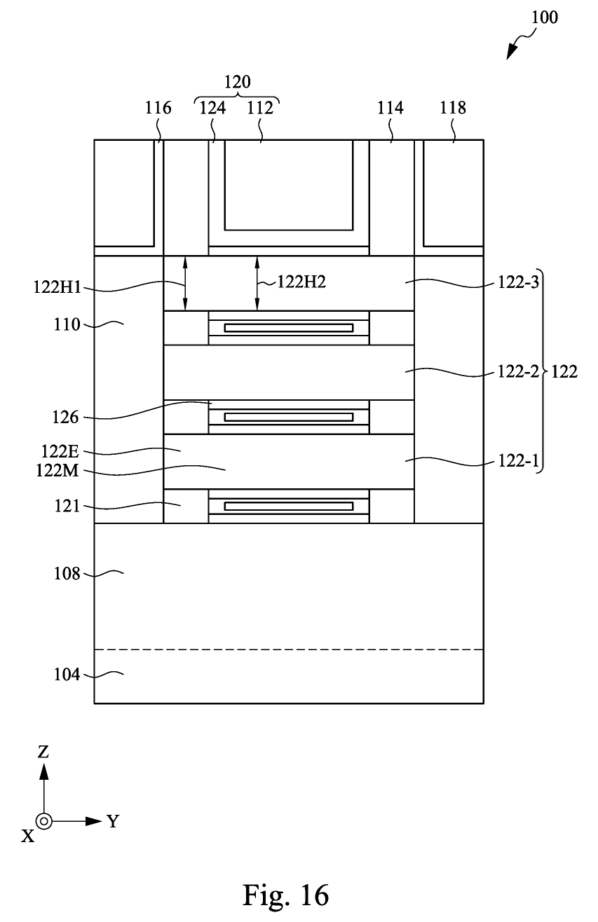

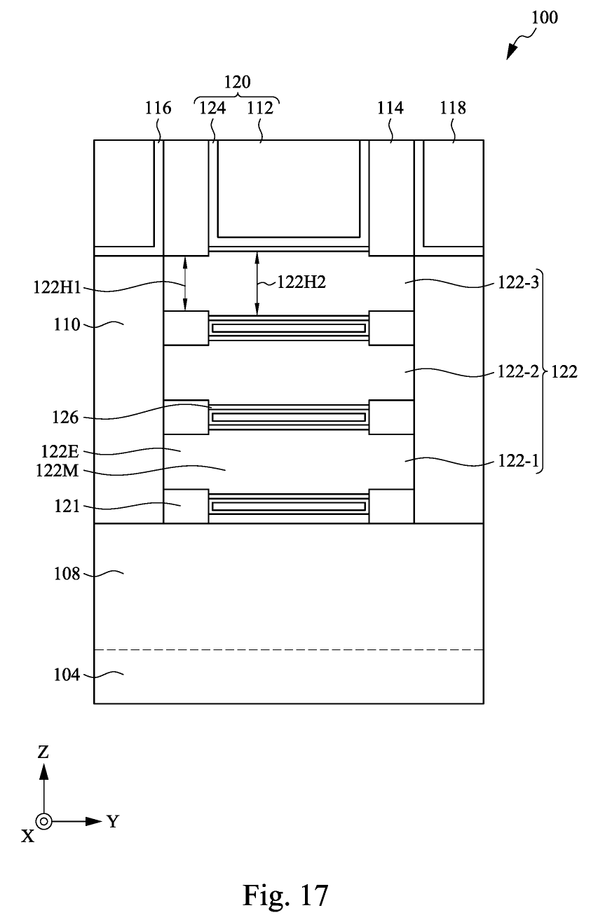

In some embodiments, as shown in FIG. 16, nanostructures 122 may not be trimmed and edge portion 122E and middle portion 122M of nanostructures 122 can have the same height. As shown in FIG. 16, height 122H1 of edge portion 122E can be substantially equal to height 122H2 of middle portion 122M. Capping semiconductor layer 126 can be in contact with inner spacers 121. In some embodiments, as shown in FIG. 17, end portion 122E may be trimmed before the formation of inner spacers 121. As a result, height 122H1 of edge portion 122E can be less than height 122H2 of middle portion 122M. Capping semiconductor layer 126 can be in contact with inner spacers 121.

Various embodiments in the present disclosure provide methods for forming capping semiconductor layer 126 in semiconductor device 100. In some embodiments, semiconductor device 100 can include nanostructures 122 as the channel structure on substrate 104. Capping semiconductor layer 126 can wrap around middle portion 122M of nanostructures 122. Gate structures 120 can wrap around capping semiconductor layer 126. S/D structures 110 can be in contact with end portion 122E of nanostructures 122. In some embodiments, nanostructures 122 can have a length 122L and capping semiconductor layer 126 can have a length 126L less than length 122L. In some embodiments, gate structures 120 can include gate dielectric layer 124 and capping semiconductor layer 126 can be disposed between nanostructures 122 and gate dielectric layer 124. In some embodiments, capping semiconductor layer 126 can include a two-dimensional (2D) semiconductor material and/or a III-V semiconductor material. In some embodiments, the 2D semiconductor material and III-V semiconductor material can have a higher carrier mobility and a lager bandgap than the semiconductor material in nanostructures 122. The 2D semiconductor material and III-V semiconductor material can improve device performance and reduce power consumption. In some embodiments, capping semiconductor layer 126 can be formed after the formation of the channel structure to reduce defects on capping semiconductor layer 126 and increase carrier mobility of semiconductor device 100.

In some embodiments, a semiconductor device includes a channel structure on a substrate, a capping semiconductor layer on a first portion of the channel structure, a gate structure wrapped around the capping semiconductor layer, and a source/drain structure in contact with a second portion of the channel structure. The gate structure includes a gate dielectric layer. The capping semiconductor layer is between the channel structure and gate dielectric layer.

In some embodiments, a semiconductor structure includes multiple nanostructures on a substrate. The multiple nanostructures have a first length. The semiconductor structure further includes a capping layer wrapped around each of the multiple nanostructures, a gate dielectric layer wrapped around the capping layer, and a metal gate wrapped around the gate dielectric layer. The capping layer has a second length less than the first length.

In some embodiments, a method includes forming a channel structure on a substrate, depositing a capping layer wrapped around the channel structure, forming a gate dielectric layer wrapped around the capping layer, and forming a metal gate wrapped around the gate dielectric layer. A length of the capping layer is less than a length of the channel structure.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a channel structure on a substrate;
a capping semiconductor layer on a first portion of the channel structure;
a gate structure wrapped around the capping semiconductor layer, wherein the gate structure comprises a gate dielectric layer, and wherein the capping semiconductor layer is between the first portion of the channel structure and the gate dielectric layer; and
a source/drain structure in contact with a second portion of the channel structure.

2. The semiconductor device of claim 1, wherein the capping semiconductor layer comprises a two-dimensional semiconductor material.

3. The semiconductor device of claim 1, wherein the capping semiconductor layer comprises a III-V semiconductor material.

4. The semiconductor device of claim 1, wherein the capping semiconductor layer comprises at least one of molybdenum disulfide, molybdenum diselenide, molybdenum ditelluride, tungsten disulfide, tungsten diselenide, gallium nitride, gallium arsenide, gallium antimonide, indium phosphide, indium antimonide, indium gallium phosphide, and indium gallium arsenide.

5. The semiconductor device of claim 1, wherein a ratio of a thickness of the capping semiconductor layer to a height of the first portion of the channel structure ranges from about 0.1 to about 0.4.

6. The semiconductor device of claim 1, further comprising an inner spacer in contact with sidewalls of the second portion of the channel structure.

7. The semiconductor device of claim 6, wherein a height of the second portion is greater than a height of the first portion, and wherein the capping semiconductor layer is in contact with the second portion.

8. The semiconductor device of claim 6, wherein a height of the second portion is substantially equal to a height of the first portion, and wherein the capping semiconductor layer is in contact with the inner spacer.

9. The semiconductor device of claim 1, further comprising an additional capping semiconductor layer wrapped around the first portion of channel structure, wherein the additional capping semiconductor layer is between the channel structure and the capping semiconductor layer.

10. The semiconductor device of claim 1, wherein a length of the capping semiconductor layer is less than a length of the channel structure.

11. A semiconductor structure, comprising:
a plurality of nanostructures on a substrate, wherein the plurality of nanostructures have a first length;
a capping layer wrapped around each of the plurality of nanostructures, wherein the capping layer has a second length less than the first length;
a gate dielectric layer wrapped around the capping layer; and
a metal gate wrapped around the gate dielectric layer.

12. The semiconductor structure of claim 11, wherein the capping layer comprises a two-dimensional semiconductor material or a III-V semiconductor material.

13. The semiconductor structure of claim 11, wherein a ratio of a thickness of the capping layer to a height of one of the plurality of nanostructures ranges from about 0.1 to about 0.4.

14. The semiconductor structure of claim 11, further comprising an inner spacer between end portions of the plurality of nanostructures, wherein the inner spacer is in contact with the capping layer.

15. The semiconductor structure of claim 11, further comprising an additional capping layer wrapped around each of the plurality of nanostructures, wherein the additional capping layer is between the capping layer and each of the plurality of nanostructures.

16. A method, comprising:
forming a channel structure on a substrate;
depositing a capping layer wrapped around the channel structure, wherein a length of the capping layer is less than a length of the channel structure;
forming a gate dielectric layer wrapped around the capping layer; and
forming a metal gate wrapped around the gate dielectric layer.

17. The method of claim 16, further comprising forming an inner spacer on an end portion of the channel structure, wherein the inner spacer is in contact with the capping layer.

18. The method of claim 16, further comprising trimming a middle portion of the channel structure, wherein the capping layer wraps around the middle portion and in contact with an end portion of the channel structure.

19. The method of claim 16, further comprising depositing an additional capping layer wrapped around the channel structure, wherein the capping layer and the additional capping layer comprises different semiconductor materials.

20. The method of claim 16, wherein depositing the capping layer comprises depositing a two-dimensional semiconductor material or a III-V semiconductor material.
